(19) United States
(12) Patent Application Publication
(10) Pub. No.: US 2026/0157177 A1
(43) Pub. Date: Jun. 4, 2026

(54) SEMICONDUCTOR PACKAGE AND MANUFACTURING METHOD THEREOF

(71) Applicant: Taiwan Semiconductor Manufacturing Company, Ltd., Hsinchu (TW)

(72) Inventors: Chien-Hua Chen, Kaohsiung City (TW); Chieh-Lung Lai, Taichung City (TW); Chia-Ling Lu, Tainan City (TW); Shuo-Mao Chen, New Taipei City (TW); Hsien-Wei Chen, Hsinchu City (TW)

(73) Assignee: Taiwan Semiconductor Manufacturing Company, Ltd., Hsinchu (TW)

(21) Appl. No.: 18/969,126

(22) Filed: Dec. 4, 2024

(51) Int. Cl. H01L 23/373; H01L 23/31; H01L 23/538; H01L 25/00; H01L 25/18

(52) U.S. Cl. CPC H10W 40/255; H10W 70/60; H10W 70/611; H10W 74/141; H10W 90/00

(57) ABSTRACT

A semiconductor package and a manufacturing method thereof are provided. The semiconductor package includes a first die, and a second die disposed aside of and spaced apart from the first die with a gap there-between, a molding compound wrapping the first and second dies, a redistribution layer disposed on the molding compound and the first and second dies, a passive component and a thermal dissipating component. A first portion of the molding compound is disposed within and filled in the gap. The passive component is disposed on the redistribution layer, and located above the first portion of the molding compound and across the gap. The thermal dissipating component is disposed on the redistribution layer and beside the passive component, separate and distanced from the passive component. The thermal dissipating component is located above a corner of at least one of the first and second semiconductor dies.

### BACKGROUND

Semiconductor dies may be processed and packaged with other semiconductor devices or dies, and the integration of different types of dies and devices in the packages is important.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1 to FIG. 7 are schematic cross-sectional views of various stages in a manufacturing method of a semiconductor package according to some exemplary embodiments of the present disclosure.

FIG. 8 is a schematic planar view of a semiconductor package according to some embodiments of the present disclosure.

FIG. 9 and FIG. 10 are schematic cross-sectional views illustrating a semiconductor package connected to a circuit substrate according to some embodiments of the present disclosure.

FIG. 11 is a schematic view showing the distribution zones of the passive devices and the thermal elements within a semiconductor package according to some embodiments of the present disclosure.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

In addition, terms, such as “first,” “second,” “third,” “fourth,” and the like, may be used herein for ease of description to describe similar or different element(s) or feature(s) as illustrated in the figures, and may be used interchangeably depending on the order of the presence or the contexts of the description.

Other features and processes may also be included. For example, testing structures may be included to aid in the verification testing of the 3D packaging or 3DIC devices. The testing structures may include, for example, test pads formed in a redistribution layer or on a substrate that allows the testing of the 3D packaging or 3DIC, the use of probes and/or probe cards, and the like. The verification testing may be performed on intermediate structures as well as the final structure. Additionally, the structures and methods disclosed herein may be used in conjunction with testing methodologies that incorporate intermediate verification of known good dies to increase the yield and decrease costs.

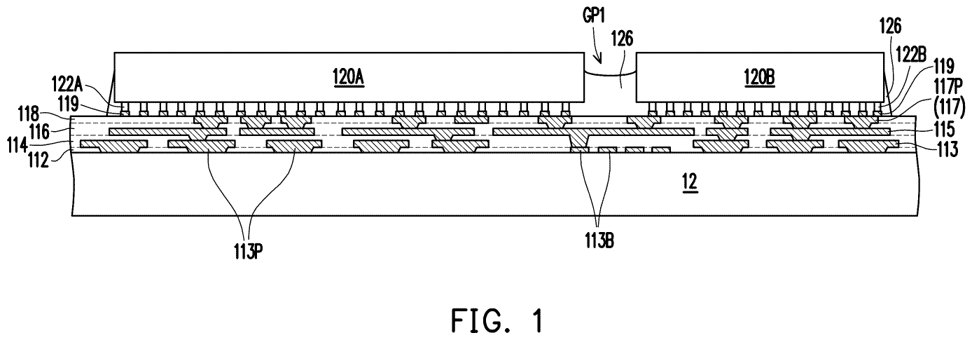

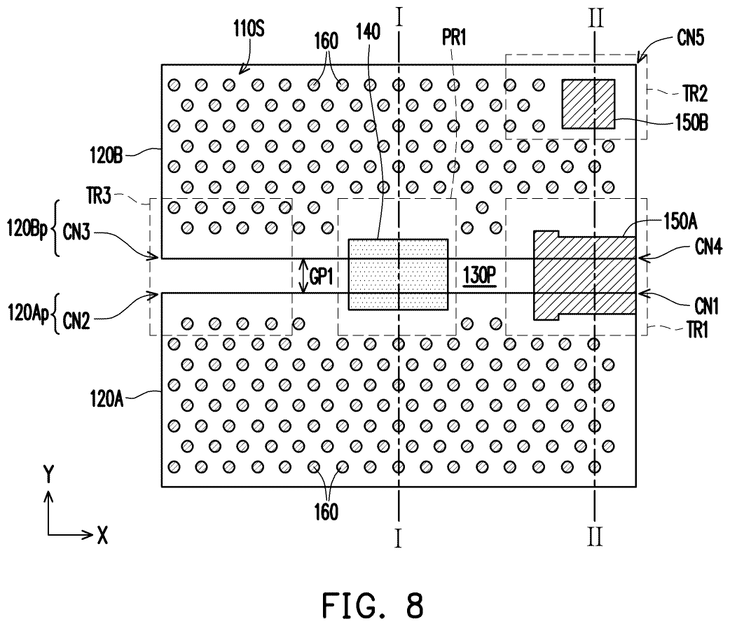

FIG. 1 to FIG. 7 are schematic cross-sectional views of various stages in a manufacturing method of a semiconductor package according to some exemplary embodiments of the present disclosure. FIG. 8 is a schematic planar view showing a portion of the semiconductor package according to some embodiments of the present disclosure.

Referring to FIG. 1, in some embodiments, a temporary carrier 12 having a debond layer (not shown) thereon for temporary joining and later detaching is provided. In some embodiments, the carrier 12 is or includes a glass substrate, a ceramic carrier, or a semiconductor material carrier such as a bulk silicon wafer. For example, the debond layer may include a light-to-heat conversion (LTHC) release layer.

Referring to FIG. 1, in some embodiments, a redistribution layer 110 is formed on the carrier 12. For example, the redistribution layer 110 formed on the carrier 12 may have a span or distribution area about the same or smaller than the carrier 12. The formation of the redistribution layer 110 includes sequentially forming more than one dielectric material layer(s) and more than one metallization layer(s) in alternation. Referring to FIG. 1, in certain embodiments, the formation of the redistribution layer 110 includes sequentially forming a first dielectric material layer 112, a first metallization layer 113, a second dielectric material layer 114, a second metallization layer 115, a third dielectric material layer 116, a third metallization layer 117, a fourth dielectric material layer 118 and metallization pads 119. In some embodiments, the formation of the redistribution layer 110 involves forming a layer of dielectric material (not shown), patterning the layer of dielectric material to form the dielectric material layer(s) with openings, depositing a metallic material filling up the openings to form metallization patterns or pads as the metallization layer(s), and the previous process steps may be repeated when needed. In some embodiments, the metallization layers 113, 115, 117 are electrically interconnected and electrically connected with the metallization pads 119.

In some embodiments, the materials of the dielectric material layers 112, 114, 116, 118 may be the same or different. In some embodiments, the materials of the dielectric material layers 112, 114, 116, 118 include one or more polymer dielectric materials such as polyimide, benzocyclobutene (BCB), polybenzooxazole (PBO), or any other suitable polymer-based dielectric materials. In some embodiments, the materials of the metallization layers 113, 115, 117 and the metallization pads 119 may be the same or different, and the materials of the metallization layers 113, 115, 117 and the metallization pads 119 may be selected from copper, cobalt, nickel, aluminum, tungsten or combinations thereof. In some embodiments, the metallization layers 113, 115, 117 may include routing traces or fan-out traces for fan-out redistribution. In some embodiments, the first metallization layer 113 may include bonding portions 113B and patterns 113P. In some embodiments, the third metallization layer 117 may include patterns 117P connected with the metallization pads 119 for receiving micro-bumps or other connector components. In some embodiments, the metallization pads 119 further optionally includes an adhesion layer, pre-solder, solder paste patterns formed on the surfaces of the pads for enhancing bonding.

Referring to FIG. 1, multiple dies including semiconductor dies 120A and semiconductor dies 120B (only one semiconductor die 120A and one semiconductor die 120B is shown) are provided and placed over the redistribution layer 110 over the carrier 12. In FIG. 1, only two dies are shown as the exemplary dies for the package structure, but it is understood that more than two dies or different types of dies may be included within the package structure. In some embodiments, the semiconductor die 120A or the semiconductor die 120B is or includes a memory die of one or more memory chips, such as high bandwidth memory (HBM) chips, dynamic random access memory (DRAM) chips or static random access memory (SRAM) chips. In some embodiments, the semiconductor die 120A or the semiconductor die 120B is or includes a logic die, and the logic die includes one or more of an application-specific integrated circuit (ASIC) chip, an analog chip, a sensor chip, a wireless application chip (such as a Bluetooth chip or a radio frequency chip) or a voltage regulator chip. In some embodiments, the semiconductor die 120A is or includes a system-on-chip (SoC) die including a controller chip, and the semiconductor die 120B is or includes a memory die including memory chips. In certain embodiments, dies and chips may be used interchangeably depending on the contexts.

In certain embodiments, in FIG. 1, the semiconductor dies 120A and the semiconductor dies 120B are respectively provided with connectors 122A and 122B facing downward, and the connectors 122A and 122B are bonded to the metallization pads 119 of the redistribution layer 110. In one embodiment, the semiconductor dies 120A and the semiconductor dies 120B are bonded to the redistribution layer 110 with their active surfaces facing the redistribution layer 110. In the embodiment, the semiconductor dies 120A and the semiconductor dies 120B are bonded to the redistribution layer 110 by performing a bonding process including a heating process. In some embodiments, the connectors 122A and 122B are or include metal pillars, micro-bumps, copper posts, copper alloy posts or other suitable metallic connectors. In some embodiments, at least one of the semiconductor dies 120A and the semiconductor dies 120B may include through substrate vias formed therein and may be bonded to the redistribution layer 110 through backside connectors.

In certain embodiments, the semiconductor dies 120A and the semiconductor dies 120B are mounted on the redistribution layer 110 over the carrier 12 and are arranged side-by-side and spaced apart from one another, and the redistribution layer 110 functions to fan-out and relocate electrical connection for the semiconductor dies 120A, 120B. It is understood that the number of the dies arranged side-by-side or stacked over another die(s) may be adjusted or modified based on the product design but are not limited by the exemplary embodiments. In some embodiments, an underfill 126 is filled between the semiconductor dies 120A and the semiconductor dies 120B and the redistribution layer 110, encapsulating the connectors 112A, 112B bonded to the metallization pads 119 for securing the attachment. In some embodiments, the underfill 126 fills between the semiconductor dies 120A and the semiconductor dies 120B and the redistribution layer 110 and surrounds the contacts 122A, 122B between the respective semiconductor die 120A, 120B and the redistribution layer 110. In one embodiment, the underfill 126 fills into the gap(s) GP1 between the semiconductor dies 120A and the semiconductor dies 120B, without fully filling up the gap(s) GP1. In one embodiment, the underfill 126 covers partially the sidewalls of the semiconductor dies 120A and the semiconductor dies 120B.

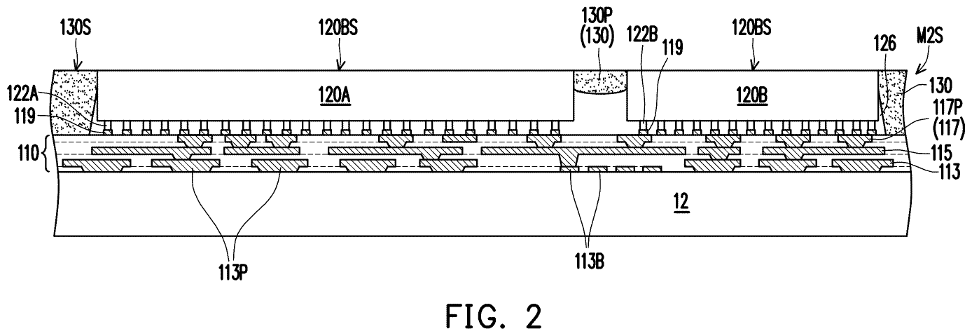

Referring to FIG. 2, in some embodiments, the semiconductor dies 120A and the semiconductor dies 120B located on the redistribution layer 110 are molded and encapsulated in a molding compound 130 to form a molded structure M2S. in some embodiments, as the molding compound 130 is formed over the redistribution layer 110 on the carrier 12, covering all of the semiconductor dies 120A, 120B, the span or spreading area of the molding compound 130 is about the same as the span of the redistribution layer 110 but is larger than the total areas of all the semiconductor dies 120A, 120B. In one embodiment, the molded structure M2S is a reconstructed wafer.

In this embodiment, the molding compound 130 at least laterally wraps the semiconductor dies 120A and the semiconductor dies 120B on the redistribution layer 110 and covers the sidewalls of the semiconductor dies 120A and the semiconductor dies 120B and the underfill 126. In one embodiment, a rail portion 130P of the molding compound 130 is filled into and fills up the cavity between the underfill 126 and the semiconductor dies 120A and the semiconductor dies 120B. In some embodiments, the material of the molding compound 130 includes epoxy resins, phenolic resins or silicon-containing resins. In some embodiments, the material of the molding compound 130 includes filler particles. In some embodiments, the molding compound 130 is over-molded and then planarized or polished to expose back surfaces 102BS of the semiconductor dies 120A and the semiconductor dies 120B. In some embodiments, the molding compound 130 is planarized through a grinding process or a chemical mechanical polishing (CMP) process. In some embodiment, the molding compound 130 is formed by transfer molding or compression molding with the back surfaces 120BS of the semiconductor dies 120A and the semiconductor dies 120B are exposed. In one embodiment, a top surface 130S of the molding compound 130 and the back surfaces 120BS of the semiconductor dies 120A and the semiconductor dies 120B are substantially levelled and flush with one another.

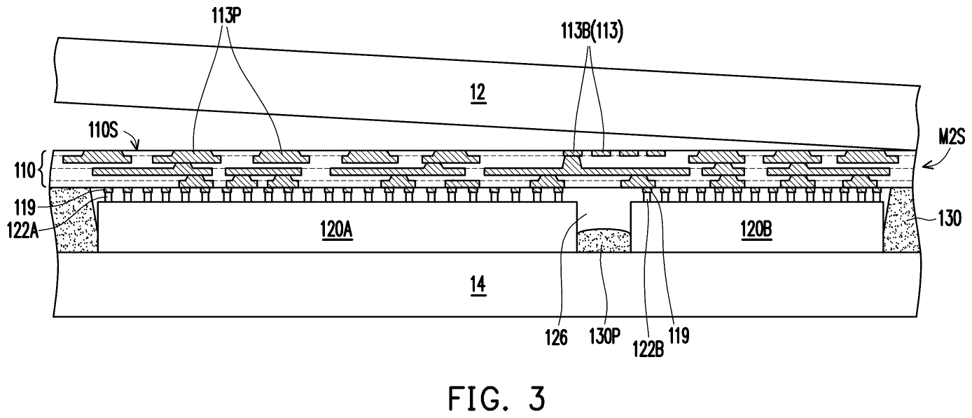

Referring to FIG. 3, in some embodiments, after another carrier 14 is attached to the molded structure M2S (attached to the back surfaces 120BS of the semiconductor dies 120A and the semiconductor dies 120B), the whole structure is turned upside down (flipped), and the carrier 12 is detached from the molded structure M2S through the debond layer (not shown) and then removed. After the carrier 12 is detached from the molded structure M2S, the first metallization layer 113 including bonding portions 113B and patterns 113P is exposed from the surface 110S of the redistribution layer 110.

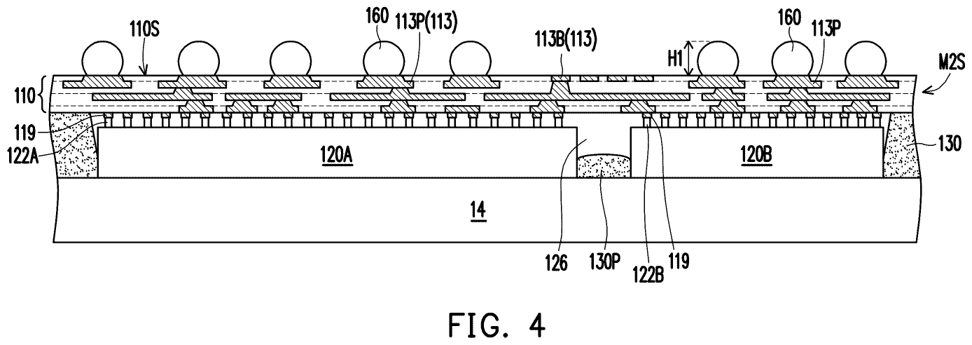

In some embodiments, referring to FIG. 4, conductive connectors 160 are formed on the redistribution layer 110. In some embodiments, the conductive connectors 160 disposed on the patterns 113P of the redistribution layer 110 are electrically connected with the redistribution layer 110. In some embodiments, the conductive connector(s) 160 has a height H1 (vertically measuring from the surface 110S in the thickness direction), and the pitch P1 between the conductive connectors 160 ranges from about 100 microns to about 200 microns or is about 150 microns. In some embodiments, the conductive connectors 160 are disposed on the redistribution layer 110 over the semiconductor dies 120A and 120B. In some embodiments, the conductive connectors 160 are disposed on the first metallization layer 113 by performing a ball placement process, and the conductive connectors 160 are fixed to the patterns 113P through a reflow process. In some embodiments, the conductive connectors 160 are, for example, electroless nickel electroless palladium immersion gold (ENEPIG) formed bumps, or controlled collapse chip connection (C4) bumps. As shown in the FIG. 4, some or all of the conductive connectors 160 are electrically connected to the semiconductor dies 120A and 120B through the redistribution layer 110. In some embodiments, the conductive connectors 160 are distributed over the span of the whole redistribution layer 110 (except for certain regions), with some conductive connectors 160 are located right above the semiconductor dies 120A, 120B, and some conductive connectors 160 are located above the molding compound 130 beside the semiconductor dies 120A, 120B (fan-out and located beyond the die spans).

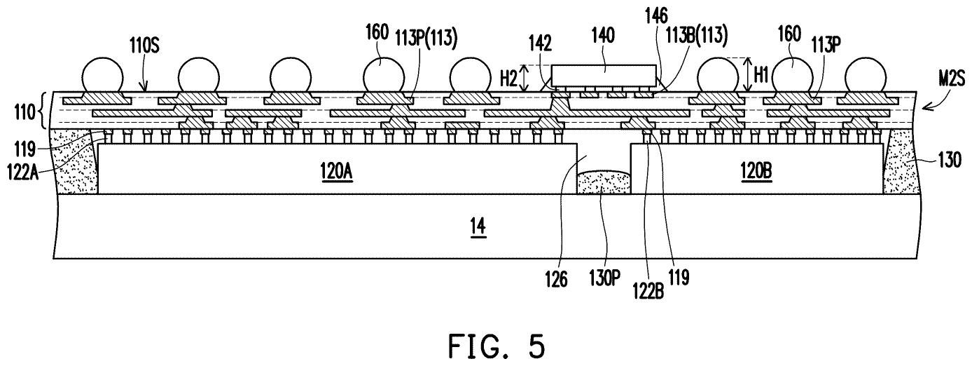

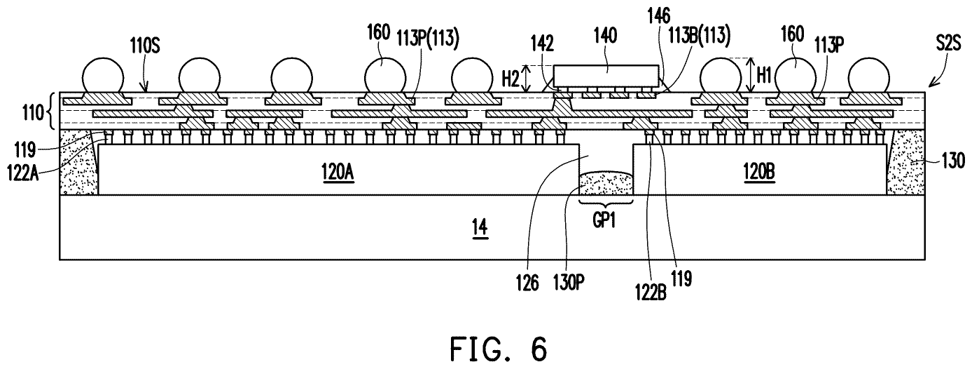

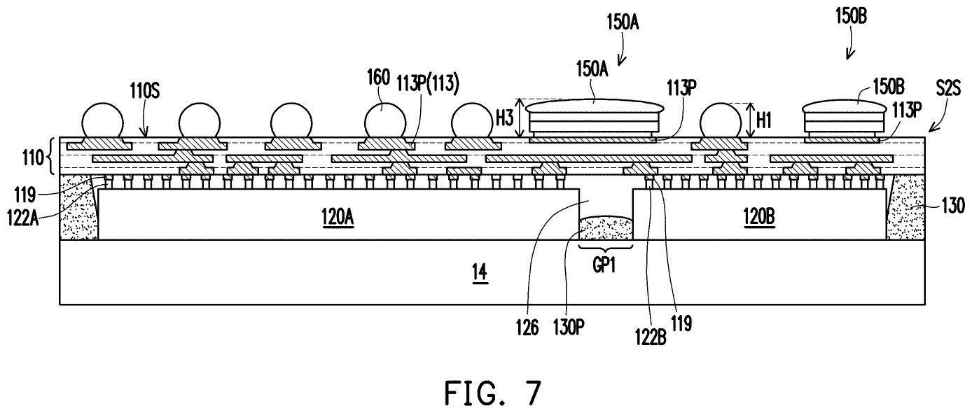

In some embodiments, referring to FIG. 5, FIG. 6 and FIG. 7, at least one passive component 140 and several thermal dissipating components 150A and 150B are provided and bonded to the redistribution layer 110, and later a singulation process is performed to the molded structure M2S to form individual packages S2S (FIG. 6 & FIG. 7). In some embodiments, the passive component 140 and thermal dissipating components 150A and 150B are disposed on the first metallization layer 113 of the redistribution layer 110, and the thermal dissipating components 150A and 150B and the passive component 140 are located beside the conductive connectors 160 on the redistribution layer 110.

Referring to FIG. 6, in some embodiments, along the cutting lanes (not shown), the singulation process is performed to cut the whole molded structure M2S (at least cutting though the redistribution layer 110 and the molding compound 130) into individual and separated semiconductor packages S2S. In one embodiment, the singulation process includes performing a wafer dicing process including mechanical sawing or laser cutting. In some embodiments, the carrier 14 may function as supporting structure and later be removed.

For example, the passive component 140 is provided with contacts 142 facing downward, for the passive component 140 mounted on the first metallization layer 113 of the redistribution layer 110, the contacts 142 of the passive component 140 are bonded and connected to the bonding portions 113B of the first metallization layer 113 of the redistribution layer 110. In some embodiments, referring to FIG. 5, the passive component 140 has a height H2 (vertically measuring from the surface 110S in the thickness direction), and the height H2 of the passive component 140 may be smaller than the height H1 of the conductive connectors 160. In one embodiment, the height H2 of the passive component 140 may be substantially the same as the height H1 of the conductive connectors 160.

In some embodiments, the contacts 142 are or include electrode contacts, metal or metal alloy pillars, posts, or other suitable metallic connectors, and the sizes or dimensions of the contacts 142 of the passive component 140 may be larger than the sizes or dimensions of the connectors 122A, 122B of the semiconductor dies 120A, 122B. In FIG. 5, only one passive component 140 is shown as the exemplary component of the package structure, but it is understood that multiple components or two or more types of passive components, electronic components or devices may be included within the package structure. In some embodiments, an underfill 146 is formed between the passive component 140 and the redistribution layer 110 and encapsulating the bonded contacts 142 and the bonding portions 113B for better attachment. In one embodiment, the bonding of the passive component 140 to the redistribution layer 110 includes performing a reflow process to bond the contacts 142 and the bonding portions 113B through a solder flux. In some embodiments, the conductive connectors 160 are disposed on the first metallization layer 113 and are fixed to the patterns 113P by performing a ball placement process and then a reflow process.

In some embodiments, as shown in the FIG. 5, some of the conductive connectors 160 are electrically connected to the passive component 140 through the redistribution layer 110. In some embodiments, the passive component 140 is electrically connected with at least one of the semiconductor dies 120A and 120B through the redistribution layer 110. For example, the semiconductor dies 120A and 120B are electrically connected through the redistribution layer 110, and the passive component 140 is electrically connected with the semiconductor dies 120A and 120B through the redistribution layer 110. In some embodiments, the passive component 140 may include one or more passive components, such as capacitors, inductors, transformers, resistors, or diodes, filters and the like. In some embodiments, the passive component 140 includes integrated passive devices (IPDs) or an IPD die.

As seen in FIG. 7, the thermal dissipating components 150A and 150B are disposed on and attached to the patterns 113P of the first metallization layer 113 of the redistribution layer 110. The thermal dissipating components 150A and 150B are electrically floating and are not electrically connected with the semiconductor dies 120A and 120B or the conductive connectors 160. The thermal dissipating components 150A and 150B mainly function to dissipate heat and transfer heat generated from the semiconductor dies 120A and 120B to the outer environments. In some embodiments, the thermal dissipating components 150A and 150B are provided with solder paste 151 thereon. In some embodiments, referring to FIG. 7, the thermal dissipating components 150A and 150B may be provided with a height H3 (vertically measuring from the surface 110S in the thickness direction), and the height H3 may be slightly larger than or substantially the same as the height H1 of the conductive connectors 160.

In some embodiments, the thermal dissipating components 150A and 150B include heat pipes or vapor chambers or other or liquid cooling devices. In one embodiment, the thermal dissipating components 150A and 150B include vapor chamber. In some embodiments, the thermal dissipating components 150A and 150B are of different sizes and have different thermal resistances. In one embodiment, the thermal dissipating component 150A has a thermal resistance lower than that of the thermal dissipating component 150B. For example, a vapor chamber is a type of two-phase passive heat transfer device that achieves an effective thermal conductivity greater than copper, through the mechanism of vaporization. Herein, the detailed structure of a vapor chamber is not shown, and a vapor chamber may include a metal or copper enclosure containing a vacuum-sealed internal cavity, and a wick structure with working fluid (such as water). Through the usage of the vapor chamber in one or more of the thermal dissipating components 150A, 150B, much better thermal conductivity is provided, and 10 times or higher thermal conductivity may be achieved when compared with copper plate.

In FIG. 7, two thermal dissipating components 150A and 150B are shown as the exemplary components, but it is understood that multiple and more than two thermal dissipating components may be arranged, the thermal dissipating components of two or more types may be included along with other elements (such as heat sink, fins), electronic components or devices for improving heat dissipation efficiency within the package structure.

Along with the thermal dissipating components 150A and 150B, the patterns 113P to which the thermal dissipating components 150A and 150B are fixed are parts of the thermally conducting path but are not parts of the electrically conducting path. Depending on the heat dissipation needs of the semiconductor dies 120A and 120B or the package S2S, multiple thermal dissipating components or thermal dissipating components of different dimensions or shapes may be arranged.

FIG. 8 is a schematic planar view showing a portion of the semiconductor package according to some embodiments of the present disclosure. FIG. 6 and FIG. 7 are schematic cross-sectional views illustrating a portion of the semiconductor package along cross-section lines I-I and II-II shown in FIG. 8. In some embodiments, from the planar view of FIG. 8, the conductive connectors 160 mounted on the redistribution layer 110 (depicted as transparent for easy illustration) are distributed over the spans of the semiconductor dies 120A and 120B except for the mounting zone(s) PR1 of the passive component(s) 140, and the mounting zones TR1, TR2 of the thermal dissipating components 150A and 150B. In some embodiments, the location of the passive component 140 is located above the gap GP1 (defined by two facing side of two adjacent semiconductor dies 120A, 120B) of two adjacent semiconductor dies 120A, 120B and is kept away from the corners (e.g. corners CN1-CN4) of the adjacent semiconductor dies 120A, 120B.

As seen in FIG. 8, the passive component 140 is located above the gap GP1 (right above the molding compound and/or underfill filled inside the gap GP1) and the span of the passive component 140 spreads across the gap GP1. From the top view, the orthogonal projection of the passive component 140 onto the planar surface (e.g. the surface 110S) is overlapped with the area (span) of the semiconductor die 120A, overlapped with the area (span) of the semiconductor die 120B and overlapped with the gap GP1 (extends across the gap GP1). The orthogonal projection is equivalent to the vertical projection in the thickness direction in three-dimensional structures. If randomly arranged, the mounting of the passive component(s) 140 may occupy the area or space save for the conductive connectors 160. For more economical and efficient arrangement of elements within the limited footprint of the package, the arrangement of the passive component 140 is designed to be disposed between the adjacent dies and above or across the gap between the adjacent dies. In some embodiments, the span (orthogonal projection) of the passive component 140 only partially overlaps with either the below semiconductor die 120A/120B, devoid of fully overlapping with either semiconductor die 120A/120B for setting more conductive connectors 160. That is, the passive component 140 is disposed right above the rail portion 130P filled inside the gap GP1 and may be partially overlapped with either or both of the adjacent dies. Also, due to stress concerns, the passive component 140 located above the gap GP1 is distanced from all of the corners CN1-CN4. In FIG. 8, in some embodiments, the span of the mounting zone PR1 extends from a peripheral portion 120Bp of the semiconductor die 120B, across the rail portion 130P in the gap GP1 and over a peripheral portion 120Ap of the semiconductor die 120A in the Y-direction, and in the X-direction, the boundary of the mounting zone PR1 is distanced and separate from the adjacent corners CN1-CN4. The mounting zone PR1 is located in a position near the middle part of the side connecting two corners CN3 and CN4 or the side connecting two corners CN2 and CN1. Depending on the size or the configuration of the passive component 140, the size/dimensions of the mounting zone (region) PR1 may be determined by adding up the area of the passive component 140 and the keep-out zone around the passive component 140.

Taking advantage of the dummy areas (e.g. the gap areas between adjacent dies), these dummy areas that are spare for the conductive connectors (e.g. C4 bumps) are used for and occupied by the passive components and/or thermal dissipating components, leading to minimum loss in the qualities of the functional connectors (e.g. input/output or signal bumps).

In some embodiments, in FIG. 8, the location of the thermal dissipating component 150A is located above the gap GP1 of two adjacent semiconductor dies 120A, 120B and overlapped with the adjacent corners CN1, CN4 (the orthogonal projection of the thermal dissipating component 150A overlapping with the corners CN1, CN4) of the two adjacent semiconductor dies 120A, 120B. That is, the thermal dissipating component 150A is disposed right above the rail portion 130P inside the gap GP1 and right above the corners CN1, CN4, and the span of the thermal dissipating component 150A is partially overlapped with either or both of the adjacent dies. In FIG. 8, in some embodiments, the span of the mounting zone TR1 extends from a peripheral portion 120Bp of the semiconductor die 120B, across the rail portion 130P and over a peripheral portion 120Ap of the semiconductor die 120A in the Y-direction, and the span of the mounting zone TR1 extends over the corners CN1, CN4 and beyond the die spans. Also, in FIG. 8, in some embodiments, the location of another thermal dissipating component 150B is located near the edge/corner CN5 of the semiconductor die 120B. In one embodiment, the orthogonal projection of the thermal dissipating component 150B falls within the span of the semiconductor die 120B, and the span of the thermal dissipating component 150B is fully overlapped with the semiconductor die 120B. Depending on the size or the configuration of the thermal dissipating component 150A/150B, the size/dimensions of the mounting zone TR1/TR2 may be determined by adding up the area of the thermal dissipating component 150A/150B and the keep-out zone needed for the thermal dissipating component 150A/150B. It is seen in FIG. 8, a mounting zone TR3 is predetermined and may be reserved for mounting additional thermal dissipating component if higher thermal conductivity is required. However, if not needed, conductive connectors 160 will be formed within this preserved zone TR3.

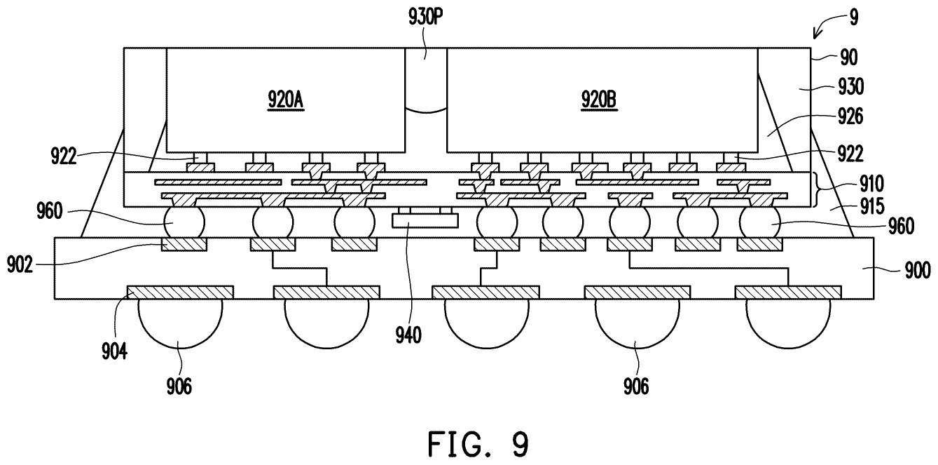

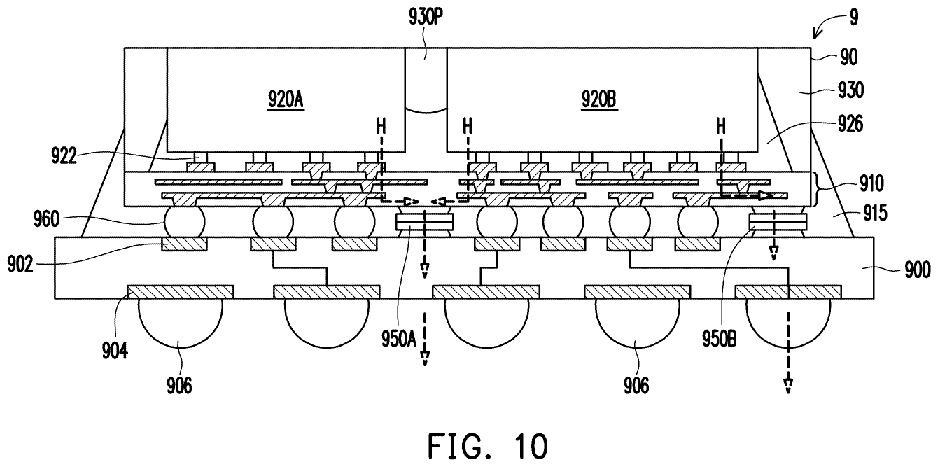

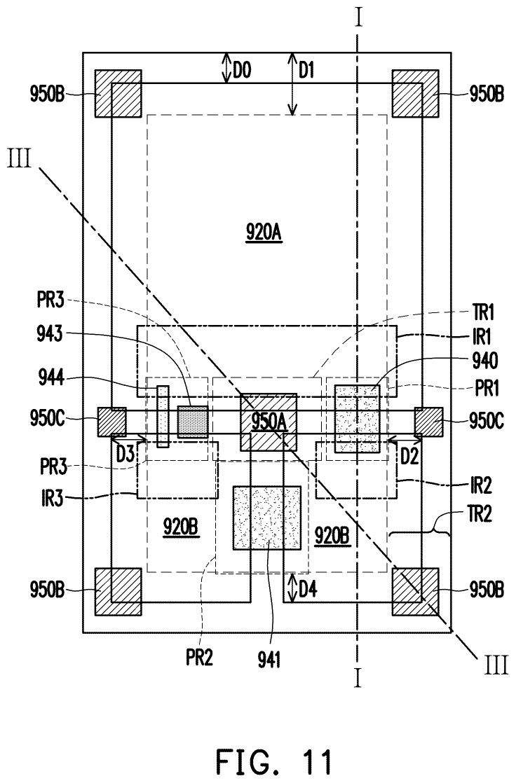

FIG. 9 and FIG. 10 are schematic cross-sectional views illustrating a semiconductor package connected to a circuit substrate according to some embodiments of the present disclosure. FIG. 11 is a schematic view showing the mounting zones of the passive devices and the thermal elements within a semiconductor package according to some embodiments of the present disclosure.

FIG. 9 and FIG. 10 are schematic cross-sectional views illustrating the semiconductor package connected to the circuit substrate along cross-section lines I-I and III-III as shown in FIG. 11. It is noted that the packages or structures in FIG. 9 and FIG. 10 and the plan arrangement in FIG. 11 is for illustration only, and the embodiments and structures in FIG. 9 and FIG. 10 are within the contemplated scope of the present disclosure that the structures described with reference to FIG. 1 to FIG. 8.

Referring to FIG. 9, FIG. 10 and FIG. 11, the package structure 90 is similar to the package structure S2S shown in the previous embodiments, but the illustration is simplified to show the relative arrangement of the semiconductor dies in the package structure 90. In some embodiments, at least one semiconductor die 920A and multiple semiconductor dies 920B are included in the package structure 90. Referring to FIG. 9, FIG. 10 and FIG. 11, the semiconductor dies 920A and 920B are located on the redistribution layer 910 at the upper side of the redistribution layer 910, and passive components 940, 941, 943, 944 and thermal dissipating components 950A, 950B and 950C are located on the redistribution layer 910 at the lower side of the redistribution layer 910 opposite to the upper side. That is, the semiconductor dies 920A, 920B are electrically connected with the passive components 940, 941, 943, 944 through the redistribution layer 910. The thermal dissipating components 950A, 950B, 950C are electrically unconnected with the semiconductor dies 920A, 920B and may be electrically floating. In some embodiments, the thermal dissipating components 950A, 950B, 950C are thermally coupled with the semiconductor dies 920A, 920B for heat transfer and heat dissipation purposes.

In some embodiments, the passive component 940, 941, 943, 944 may include one or more passive components, such as capacitors, inductors, transformers, resistors, or diodes, filters and the like. In some embodiments, the passive component 940, 941, 943 or 944 includes integrated passive devices (IPDs) or an IPD die. In some embodiments, the thermal dissipating components 950A, 950B, 950C include heat pipes or vapor chambers or other or liquid cooling devices. In one embodiment, the thermal dissipating components 950A, 950B, 950C include vapor chambers. In some embodiments, the thermal dissipating components 950A, 950B, 950C are of different sizes and have different thermal resistances. In one embodiment, the thermal dissipating component 950A has a thermal resistance lower than that of the thermal dissipating component 950B or 950C.

As seen in FIG. 9 and FIG. 10, the semiconductor dies 920A and 920B are arranged side-by side on the redistribution layer 910, the semiconductor dies 920A and 920B are bonded to the redistribution layer 910 through connectors 922 along with an underfill 926 filled between the semiconductor die 920A, the semiconductor dies 920B and the redistribution layer 910 and surrounding the connectors 922. Also, the molding compound 930 disposed on the redistribution layer 910 at least laterally wraps the semiconductor dies 920A and 920B and fully covers the sidewalls of the semiconductor dies 920A and 920B. In some embodiments, the semiconductor dies 920A and 920B are different type of dies, or perform different functions. In some embodiments, the semiconductor die 920A is or includes a SoC die, and the semiconductor dies 920B each is or includes a memory die. In some embodiments, the passive components 940, 941, 943, 944 are different types of components. In some embodiments, the passive components 940, 941, 943 and 944 may perform the same or similar functions but are formed as components in different dimensions or shapes. In some embodiments, the thermal dissipating components 950A, 950B, 950C perform the same or similar functions but are formed as components in different dimensions or shapes.

In FIG. 9 and FIG. 10, the package structure 90 is bonded to a circuit substrate 900 through conductive connectors 960 to form a package 9. In some embodiments, an underfill 915 is formed between the package structure 90 and the circuit substrate 900, filling the space between the package structure 90 and the circuit substrate 900, encapsulating the conductive connectors 960 and the passive components 940, 941, 943, 944 as well as the thermal dissipating components 950A, 950B, 950C. in one embodiment, the underfill 915 covers partially the sidewalls of the package structure 90. After the package structure 90 is bonded to the circuit substrate 900, the passive components 940, 941, 943, 944 with heights smaller than the conductive connectors 960, the passive components 940, 941, 943, 944 may be physically separate from and spaced apart from the top surface of the circuit substrate 900. After the package structure 90 is bonded to the circuit substrate 900, the thermal dissipating components 950A, 950B, 950C with heights slightly larger or about the same as the conductive connectors 960, the thermal dissipating components 950A, 950B, 950C are physically connected with the circuit substrate 900 and is in physical contact with the top surface of the circuit substrate 900, so that the heat H (transferring directions shown in arrows) generated from the semiconductor dies 920A, 920B is transferred through the thermal dissipating components 950A/950B/950C to the circuit substrate 900 and further to the outer environment.

In some embodiments, the package 9 is a Chip-On-Wafer-On-Substrate (CoWoS) structure. In some embodiments, the circuit substrate 900 includes a build-up board, a printed circuit board, a laminated board or a flexible laminate board. In some embodiments, the circuit substrate 900 may include one or more embedded devices including active devices, passive devices, or a combination thereof. In some embodiments, the circuit substrate 900 includes pads 902 and 904 located on two opposite sides of the circuit substrate 900 to receive conductive connectors 960 and ball connectors 906, and the circuit substrate 900 provides dual-side electrical connection. In certain embodiments, ball connectors 906 formed on the pads 904 of the circuit substrate 900. In some embodiments, the ball connectors 906 include solder balls, ball grid array (BGA) connectors, controlled collapse chip connection (C4) bumps. In some embodiments, ball connectors 906 formed on the bottom surface of the circuit substrate 900 for further electrical connection.

In some embodiments, the sizes or dimensions of the ball connectors 906 are larger than the sizes or dimensions of the conductive connectors 960, and the conductive connectors 960 are larger than the contacts 922 in the package structure 90. Through these conductive connections, the semiconductor dies 920A, 920B of smaller pitches are electrically connected with the passive component 940, 941, 943, 944 of a larger pitch and the circuit substrate 900 of further larger pitches.

From the planar view of FIG. 11, the semiconductor dies 920A and 920B are rectangular or tetragonal shaped, and are spaced apart from one another with gaps existing between the semiconductor dies 920A and 920B and between the semiconductor dies 920B. As described in previous contexts, the molding compound 930 filled within the gaps between the semiconductor dies 920A and 920B and between the semiconductor dies 920B is referred to as rail portions 930P of the molding compound 930, and the semiconductor dies 920A and 920B are separate by the rail portions 930P. In FIG. 11, the mounting zones may be illustrated and shown as rectangular circles in dotted lines.

Referring to FIG. 11, for easy illustration, the redistribution layer 910 is shown as transparent, it is seen that the span of the molding compound 930 surrounding the semiconductor dies 920A and 920B is larger, with a distance D0 measuring from either the periphery of the semiconductor die 920A or the periphery of the semiconductor die 920B, and a ring-shaped mounting zone TR2 for thermal dissipating components 950B and 950C is defined along the periphery of the molding compound 930 with a distance D1. In one embodiment, the distance D0 ranges from about 700 microns to about 1000 microns. In one embodiment, the distance D1 ranges from about 1350 microns to about 1650 microns. In one embodiment, the ring-shaped mounting zone TR2 extends across the corners of the semiconductor dies 920A and 920B, and the thermal dissipating components 950B and 950C are mounted over the corners of the semiconductor dies 920A and 920B. Referring to FIG. 11, the locations of the thermal dissipating components 950B are overlapped with the corners of the semiconductor dies 920A and 920B (each being overlapped with one corner of either semiconductor die 920A or 920B), and the locations of the thermal dissipating components 950C are overlapped with the facing corners (two corners) of the semiconductor dies 920A and 920B. That is, the orthogonal projections of the thermal dissipating components 950B fall within the mounting zone TR2 and are overlapped with the corners of the semiconductor dies 920A and 920B (each being overlapped with one corner of either semiconductor die 920A or 920B), and the orthogonal projections of the thermal dissipating components 950C fall within the mounting zone TR2 and are overlapped with the two facing corners of the two adjacent semiconductor dies 920A and 920B.

In the planar view of FIG. 11, in some embodiments, a mounting zone TR1 spreads across two facing corners of the two adjacent semiconductor dies 920B and across the gaps between the two adjacent semiconductor dies 920B and the semiconductor die 920A (i.e. T-shaped gap between the dies 920A and 920B), and the orthogonal projection of the thermal dissipating component 950A falls within the mounting zone TR1 and is partially overlapped with the three semiconductor dies 920A and 920B. As seen in FIG. 11, the location of the thermal dissipating component 950A is overlapped with the two facing corners of the two adjacent semiconductor dies 920B, overlapped with the rail portion 930P located between three semiconductor dies 920A and 920B and overlapped with a peripheral portion of the semiconductor die 920A.

Referring to FIG. 11, the mounting zones PR1, PR2 and PR3 of the passive components 940, 941, 943 and 944 are located above the rail portions 930P within the gaps defined by two facing side of two adjacent semiconductor dies 920A, 920B and two adjacent semiconductor dies 920B, but are distanced from the corners of the adjacent semiconductor dies 920A and 920B (e.g. kept away from the corners of the adjacent semiconductor dies 920A and 920B). As seen in FIG. 11, the mounting zones PR1 is distanced from the corner of the semiconductor die 920A or 920B with a shortest distance D2, the mounting zones PR2 is distanced from the corners of the semiconductor die 920B with a shortest distance D4, and the mounting zones PR3 is distanced from the corners of the semiconductor die 920A or 920B with a shortest distance D3. In one embodiment, the keep-out distance D2, D3 or D4 ranges from about 600 microns to about 800 microns, or is at least larger than about 650 microns.

In some embodiments, as seen in FIG. 11, the location of the passive component 940 that is located within the mounting zone PR1 is overlapped with the rail portion 930P located between the adjacent semiconductor dies 920A and 920B and overlapped with peripheral portions of the semiconductor dies 920A and 920B. That is, the orthogonal projection of the passive component 940 is overlapped with the two facing sides of the semiconductor dies 920A and 920B (without being overlapped with any corner of either semiconductor die 920A or 920B). In some embodiments, the location of the passive component 941 that is located within the mounting zone PR2 is overlapped with the rail portion 930P located between the adjacent semiconductor dies 920B and overlapped with peripheral portions of the semiconductor dies 920B. That is, the orthogonal projection of the passive component 941 is overlapped with the two facing sides of the semiconductor dies 920B (without being overlapped with any corner of semiconductor die 920B). In some embodiments, the locations of the passive components 943 and 944 that are located within the mounting zone PR3 are overlapped with the rail portion 930P located between the adjacent semiconductor dies 920A and 920B and overlapped with peripheral portions of the semiconductor dies 920A and 920B. That is, the orthogonal projection of either the passive component 943 or the passive component 944 is overlapped with the two facing sides of the semiconductor dies 920A and 920B (without being overlapped with any corner of either semiconductor die 920A or 920B).

In FIG. 11, in some embodiments, for either of the passive component 940, 941, 943, 944, its vertical projection (along the thickness direction) is at least partially overlapped with two adjacent semiconductor dies 920A and 920B. In some embodiments, the span of either passive component 940, 943 or 944 spreads from one semiconductor die 920A to another semiconductor die 920B and extends across the two facing sides of the adjacent semiconductor dies 920A and 920B. In some embodiments, the span of the passive component 941 spreads from one semiconductor die 920B to another semiconductor die 920B and extends across the two facing sides of the adjacent semiconductor dies 920B. That is, the dimension (width) of either of the passive component 940, 941, 943, 944 is larger than the gap width or the width of the rail portion 930P, so that either of the passive component 940, 941, 943, 944 may be like patches, mounted between the most adjacent dies and kept out from the most stressful corner areas of the dies. In one embodiment, the width of the rail portion 930P ranges from about 80 microns to about 200 microns, or from about 100 microns to about 150 microns. It is possible that the gap or spacing between the adjacent dies may be adjusted based on the product design.

As seen in FIG. 11, in some embodiments, the locations of the passive components 940, 943 and 944 are overlapped with signal input/output regions IR1, IR2 and IR3 of the adjacent semiconductor dies 920A and 920B. Namely, the orthogonal projection of the passive component 940 is overlapped with both of the signal input/output regions IR1 and IR2 of the semiconductor dies 920A and 920B, and the orthogonal projection of the passive component 943 or 944 (or both) is overlapped with both of the signal input/output regions IR1 and IR3 of the semiconductor dies 920A and 920B.

Compared with the package structure with the passive component located right below the span of the die (i.e. “within die span”, location-wise fully overlapped with the die), the package structure having the passive component located over the gap between the dies (i.e. “over the gap”, location-wise fully across the die gap and partially overlapped with the die), the stress risk level is improved by at least 20%, and the risk of delamination or cracking is significantly lessened. Through the “over the gap” arrangement, the power integrity is improved as observed from Z-PDN, the Z parameter of the frequency domain of the power distribution network (PDN), for example, the suppression frequency band is improved by more than 200%, the resonance point (impedance) is lowered by 66.6% and the peak (maximum Z-PDN) is improved by 33.4%, relative to the “within die span” arrangement. Hence, through such arrangement of the passive component within the package structure, the voltage fluctuation and power noise are effectively suppressed and lower PDN impedance is achieved.

The disclosure is not limited neither by the type nor the number of semiconductor packages 90 connected to the circuit substrate 900. In the drawings of the present disclosure, an integrated fan-out (InFO) package is shown as the semiconductor package unit for purpose of illustration. However, it will be apparent that other types of semiconductor packages may be used to produce semiconductor device package structures including the circuit substrate disclosed herein, and all these semiconductor devices are intended to fall within the scope of the present description and of the attached claims. For example, Chip-On-Wafer-On-Substrate (CoWoS) structures, three-dimensional integrated circuit (3DIC) structures, Chip-on-Wafer (CoW) packages, Package-on-Package (PoP) structures may all be used as the semiconductor package units, alone or in combination.

According to some embodiments, a package includes a first semiconductor die, and a second semiconductor die disposed aside of the first semiconductor die and spaced apart from the first semiconductor die with a gap there-between, a molding compound laterally wrapping the first and second semiconductor dies, a redistribution layer disposed on the molding compound and the first and second semiconductor dies, a passive component and a thermal dissipating component. A first portion of the molding compound is disposed within and filled in the gap. The passive component is disposed on the redistribution layer, and the passive component is located above the first portion of the molding compound and across the gap. The thermal dissipating component is disposed on the redistribution layer and beside the passive component, separate and distanced from the passive component. The thermal dissipating component is located above a corner of at least one of the first and second semiconductor dies.

According to some embodiments, a package includes a circuit substrate and a molded structure, disposed on the circuit substrate and connected with the circuit substrate through conductive connectors. The molded structure includes a redistribution layer, a first semiconductor die, a second semiconductor die and a third semiconductor die disposed on the redistribution layer, a molding compound laterally wrapping the first, second and third semiconductor dies, a first thermal dissipating component and a first passive component disposed on a second side of the redistribution layer opposite to the first side. The first semiconductor die, the second semiconductor die and the third semiconductor die are disposed side-by-side on a first side of the redistribution layer and spaced apart from one another with gaps there-between. First portions of the molding compound are filled in and located within the gaps between the first, second and third semiconductor dies. An orthogonal projection of the first thermal dissipating component is overlapped with the first portions of the molding compound between the first, second and third semiconductor dies and between the second and third semiconductor dies. The first passive component is separate from the first thermal dissipating component and distanced from corners of the first, second and third semiconductor dies. An orthogonal projection of the first passive component is overlapped with the first portion of the molding compound between two semiconductor dies of the first, second and third semiconductor dies.

According to some embodiments, a manufacturing method is provided. A redistribution layer is formed. A first semiconductor die, a second semiconductor die and a third semiconductor die are disposed and bonded onto a first side of the redistribution layer, side-by-side and spaced apart from one another with gaps therebetween. The first, second and third semiconductor dies are molded with a molding compound to form a molded structure. First portions of the molding compound fill into the gaps between the first, second and third semiconductor dies. A first passive component is mounted and bonded onto a second side of the redistribution layer opposite to the first side and a first thermal dissipating component is connected to the second side of the redistribution layer. An orthogonal projection of the first thermal dissipating component is overlapped with the first portions of the molding compound between the first, second and third semiconductor dies and between the second and third semiconductor dies, and an orthogonal projection of the first passive component is overlapped with the first portion of the molding compound between two semiconductor dies of the first, second and third semiconductor dies and distanced from corners of the first, second and third semiconductor dies. A singulation process is performed to the molded structure to form packages. A circuit substrate is provided and the circuit substrate is connected with at least one package.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A package structure, comprising:
a first semiconductor die, and a second semiconductor die disposed aside of the first semiconductor die and spaced apart from the first semiconductor die with a gap there-between;
a molding compound laterally wrapping the first and second semiconductor dies, wherein a first portion of the molding compound is disposed within and filled in the gap;
a redistribution layer disposed on the molding compound and the first and second semiconductor dies;
a passive component disposed on the redistribution layer, wherein the passive component is located above the first portion of the molding compound and across the gap; and
a thermal dissipating component, disposed on the redistribution layer and beside the passive component, separate and distanced from the passive component, wherein the thermal dissipating component is located above a corner of at least one of the first and second semiconductor dies.

2. The structure of claim 1, wherein the thermal dissipating component is located above the first portion of the molding compound and across the gap and located above two facing corners of the first and second semiconductor dies.

3. The structure of claim 2, wherein an orthogonal projection of the thermal dissipating component is overlapped with the first portion and partially overlapped with the first and second semiconductor dies.

4. The structure of claim 3, further comprising another thermal dissipating component disposed on the redistribution layer, beside the passive component, and an orthogonal projection of the another thermal dissipating component is overlapped with a corner of at least one of the first and second semiconductor dies.

5. The structure of claim 4, wherein the thermal dissipating component has a thermal conductivity larger than that of the another thermal dissipating component.

6. The structure of claim 1, wherein an orthogonal projection of the passive component is overlapped with the first portion and partially overlapped with the first and second semiconductor dies.

7. The structure of claim 1, wherein the passive component is electrically connected with at least one of the first and second semiconductor dies through the redistribution layer.

8. The structure of claim 1, wherein the passive component includes integrated passive devices.

9. A package structure, comprising:
a circuit substrate; and
a molded structure, disposed on the circuit substrate and connected with the circuit substrate through conductive connectors, the molded structure comprising:
a redistribution layer;
a first semiconductor die, a second semiconductor die and a third semiconductor die disposed on the redistribution layer, wherein the first semiconductor die, the second semiconductor die and the third semiconductor die are disposed side-by-side on a first side of the redistribution layer and spaced apart from one another with gaps there-between;
a molding compound laterally wrapping the first, second and third semiconductor dies, wherein first portions of the molding compound are filled in and located within the gaps between the first, second and third semiconductor dies;
a first thermal dissipating component disposed on a second side of the redistribution layer opposite to the first side, wherein an orthogonal projection of the first thermal dissipating component is overlapped with the first portions of the molding compound between the first, second and third semiconductor dies and between the second and third semiconductor dies; and
a first passive component disposed on the second side of the redistribution layer, separate from the first thermal dissipating component and distanced from corners of the first, second and third semiconductor dies, wherein an orthogonal projection of the first passive component is overlapped with the first portion of the molding compound between two semiconductor dies of the first, second and third semiconductor dies.

10. The structure of claim 9, further comprising a second thermal dissipating component disposed on the second side of the redistribution layer, spaced apart from the first thermal dissipating component and the first passive component, wherein an orthogonal projection of the second thermal dissipating component is overlapped with at least one corner of the first, second and third semiconductor dies.

11. The structure of claim 10, wherein the orthogonal projection of the second thermal dissipating component is overlapped with one corner of one of the first, second and third semiconductor dies.

12. The structure of claim 10, wherein the orthogonal projection of the second thermal dissipating component is overlapped with two facing corners of two semiconductor dies of the first, second and third semiconductor dies.

13. The structure of claim 9, wherein the first semiconductor die performs a different function from the second and third semiconductor dies and a size of the first semiconductor die is larger than those of the second and third semiconductor dies.

14. The structure of claim 13, further comprising a second passive component disposed on the second side of the redistribution layer, spaced apart from the first thermal dissipating component and the first passive component, wherein the first passive component is located above and extends across the first portion of the molding compound between the first and second semiconductor dies, and the second passive component is located above and extends across the first portion of the molding compound between the second and third semiconductor dies.

15. The structure of claim 14, further comprising a third passive component disposed on the second side of the redistribution layer, spaced apart from the first thermal dissipating component and the first and second passive components, wherein the third passive component is located above and extends across the first portion of the molding compound between the first and third semiconductor dies.

16. The structure of claim 9, wherein the first passive component includes integrated passive devices, and the first thermal dissipating component includes a vapor chamber.

17. A manufacturing method, comprising:
forming a redistribution layer;
disposing and bonding a first semiconductor die, a second semiconductor die and a third semiconductor die onto a first side of the redistribution layer, side-by-side and spaced apart from one another with gaps there-between;
molding the first, second and third semiconductor dies with a molding compound to form a molded structure, wherein first portions of the molding compound fill into the gaps between the first, second and third semiconductor dies;
mounting and bonding a first passive component onto a second side of the redistribution layer opposite to the first side and connecting a first thermal dissipating component onto the second side of the redistribution layer, wherein an orthogonal projection of the first thermal dissipating component is overlapped with the first portions of the molding compound between the first, second and third semiconductor dies and between the second and third semiconductor dies, and wherein an orthogonal projection of the first passive component is overlapped with the first portion of the molding compound between two semiconductor dies of the first, second and third semiconductor dies and distanced from corners of the first, second and third semiconductor dies;
performing a singulation process to the molded structure to form packages; and
providing a circuit substrate and connecting the circuit substrate with at least one package.

18. The method of claim 17, further comprising dispensing an underfill between the circuit substrate and the at least one package.

19. The method of claim 17, wherein the first passive component includes integrated passive devices, and the first thermal dissipating component includes a vapor chamber.

20. The method of claim 17, wherein the first passive component is electrically connected with the first, second and third semiconductor dies via the redistribution layer.
